(19) United States
(12) Patent Application Publication
(10) Pub. No.: US 2025/0093180 A1
(43) Pub. Date: Mar. 20, 2025

(54) TEST SOCKET FOR A COMPONENT

(71) Applicant: SAMSUNG ELECTRONICS CO., LTD., Suwon-si (KR)

(72) Inventor: Jee-Hoon Ka, Suwon-si (KR)

(21) Appl. No.: 18/765,078

(22) Filed: Jul. 5, 2024

(30) Foreign Application Priority Data
Sep. 14, 2023 (KR) 10-2023-0122780

(51) Int. Cl. G01D 3/036; H05B 1/02

(52) U.S. Cl. CPC G01D 3/036; H05B 1/02

(57) ABSTRACT

A test apparatus includes an image sensor module including a controller configured to generate a pulse width modulation signal to control a temperature of an image sensor module to be tested, and a test socket configured to emit heat to the image sensor module based on the pulse width modulation signal. The controller may control a duty ratio of the pulse width modulation signal based on a current temperature of the image sensor module, a target temperature and a criteria temperature range, and the criteria temperature range is a temperature range within a preset range from the target temperature.

### CROSS-REFERENCE TO RELATED APPLICATION(S)

This U.S. non-provisional application claims priority under 35 USC § 119 to Korean Patent Application No. 10-2023-0122780, filed on Sep. 14, 2023, in the Korean Intellectual Property Office, the disclosure of which is herein incorporated by reference in its entirety.

### BACKGROUND

Many components are tested at high-temperature. For example, the overall quality of an image sensor module is tested at room temperature, and a high-temperature test is then performed. The high-temperature test is performed using a temperature test apparatus, which may be bulky, expensive, and noisy. In addition, when the high-temperature chamber is used, not only the component to be tested but also other components of a substrate may be exposed to high temperature. Therefore, to satisfy a high-temperature test, all of the components of the substrate disposed inside the high-temperature chamber may be designed to operate at high temperatures. Otherwise, the high-temperature test of an component may result in errors.

### SUMMARY

Some implementations according to this disclosure provide test sockets optimized for an component, test apparatuses including the same, and methods of operating the same. For example, the component to be tested may be an image sensor.

According to some implementations, a test apparatus includes a controller configured to generate a pulse width modulation signal to control a temperature of an image sensor module to be tested, and a test socket configured to emit heat to the image sensor module based on the pulse width modulation signal. The controller may control a duty ratio of the pulse width modulation signal based on a current temperature of the image sensor module, a target temperature and a criteria temperature range. The criteria temperature range may be a temperature range within a preset range from the target temperature.

According to some implementations, a test socket includes a cover covering an upper portion of an image sensor module to be tested, an aperture configured to open and close, a heater configured to turn on and turn off based on a pulse width modulation signal and configured to emit heat to the image sensor module to cause a current temperature of the image sensor module to reach a target temperature, a socket temperature sensor configured to measure the current temperature, a bottom plate disposed below the image sensor module and accommodating the heater and the socket temperature sensor, and a support supporting the bottom plate.

According to some implementations, a test method incudes receiving predetermined field of view (FOV) information and target set temperature for temperature evaluation of an image sensor module to be tested, receiving a current temperature inside a test socket, controlling the test socket, based on the current temperature being outside a criteria temperature range and based on the current temperature being lower than the target temperature, to cause the current temperature to increase using a pulse width modulation signal, controlling the test socket, based on the current temperature being within the criteria temperature range and based on the current temperature being lower than the target temperature, to cause the current temperature to decrease using the pulse width modulation signal, controlling the test socket based on the FOV information and driving the image sensor module to capture an image based on the current temperature being maintained at the target temperature for a predetermined time, and outputting a result of the temperature evaluation of the image sensor module, the temperature evaluation based on the captured image.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a block diagram of a test apparatus according to some implementations.

FIG. 2 is a block diagram illustrating an example of a test apparatus according to some implementations.

FIG. 3 is a block diagram illustrating an example of a test apparatus implemented in hardware.

FIG. 4 is a flowchart illustrating an example of operation of a temperature controller.

FIG. 5 is a flowchart illustrating an example of operation of a temperature controller.

FIGS. 6 and 7 are graphs illustrating an example of operation of a temperature controller.

FIG. 8A is a diagram illustrating an example of a cross-sectional view of a test socket.

FIG. 8B is a diagram illustrating an example of a test socket.

FIGS. 9A and 9B are diagrams illustrating an example of operation of an aperture of a test socket.

### DETAILED DESCRIPTION

Hereinafter, various examples will be described with reference to the accompanying drawings.

In this disclosure, various examples of a test apparatus for testing image sensor modules,. However, this disclosure may include not only the test apparatus for testing image sensor modules, but also a test apparatus for testing different components from the image sensor module. For example, the components to be tested may be, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), power managing integrated circuit (PMIC), etc. Therefore, the scope should not be limited to the test apparatus for testing image sensor modules.

Some implementations according to this disclosure provide a test apparatus that is specialized for testing image sensor modules and is capable of stably performing temperature evaluation of image sensors.

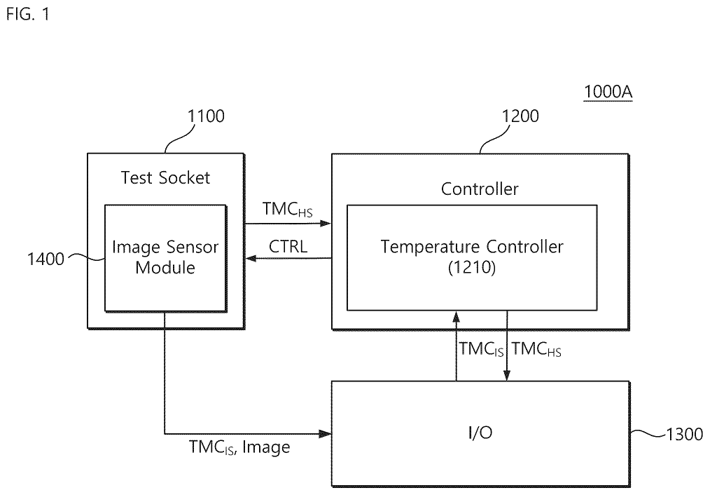

FIG. 1 is a block diagram of a test apparatus 1000A according to some implementations. The test apparatus 1000A may fix a removable test socket 1100 to a test module substrate including a component to be tested. For an example, the component to be tested may be an image sensor module 1400. Thus, the image sensor module 1400 may be disposed inside the test socket 1100. While the image sensor module 1400 is disposed inside the test socket 1100, the test apparatus 1000A may test various characteristics of the image sensor module 1400 at high temperature. As described throughout this disclosure, the test apparatus 1000A may prevent components, other than the image sensor module, from being exposed to high temperatures using the test socket 1100 optimized for the image sensor module. Accordingly, test errors caused by the components other than the image sensor module 1400 may be reduced or prevented, and temperature evaluation of the image sensor module 1400 may be efficiently performed at high temperature.

A more detailed description will be provided with reference to FIG. 1. The test apparatus 1000A in some implementations may include a test socket 1100, a controller 1200, an input/output unit (I/O) 1300, and an image sensor module 1400. In some implementations, the image sensor module 1400 may be distinct from the test apparatus 1000A.

The test socket 1100 may be configured to accommodate the image sensor module 1400 therein. For example, the image sensor module 1400 may be attached to a test module substrate. The test module substrate, to which the image sensor module 1400 is attached, may be inserted into the test socket 1100 to be fixed thereto. Accordingly, the image sensor module 1400 may be disposed inside the test socket 1100.

The test socket 1100 may be configured to test various characteristics of the image sensor module at high temperatures. For example, the test socket 1100 may emit heated air to the image sensor module 1400 to perform a high-temperature test. Thus, a temperature of the image sensor module 1400 may increase.

According to some implementations, a target set temperature for temperature evaluation may be input to the test apparatus 1000A. Then, the test socket 1100 may emit heated air to the image sensor module 1400 based on the target set temperature, so that air around the image sensor module 1400 may be heated. Then, the high-temperature test of the image sensor module 1400 may be performed when the image sensor module 1400 is maintained at the target set temperature.

According to some implementations, the test socket 1100 may include a heater. The heater may be turned on/off based on a control signal CTRL. The heater may emit heat to the image sensor module 1400 such that current temperature of the image sensor module 1400 reaches target set temperature, based on the control signal CTRL. The test socket 1100 may be provided with components, such as a Peltier element, a heater, a heated-air emitter, and/or the like, to emit heat to the image sensor module 1400, but implementations are not limited thereto.

The current temperature of the image sensor module 1400 may be a temperature measured by the test socket 1100 or a temperature measured by the image sensor module 1400.

For example, the test socket 1100 may include a socket temperature sensor, and the current temperature may be a temperature TMC_{HS} measured by a socket temperature sensor disposed inside the test socket 1100. In this case, the temperature TMC_{HS} measured by the socket temperature sensor may be transmitted to a temperature controller 1210, e.g., of the controller 1200.

As another example, the image sensor module 1400 may include a module temperature sensor, and the current temperature may be a temperature TMC_{IS} measured by the module temperature sensor of the image sensor module 1400. The temperature TMC_{IS} measured by the module temperature sensor may be transmitted to the input/output unit 1300 together with other output data of the image sensor module 1400, such as an image. Then, the input/output unit 1300 may transmit the temperature TMC_{IS}, measured by the module temperature sensor, to the temperature controller 1210. One or both of the socket temperature sensor and the module temperature sensor may be included, depending on the implementation.

The controller 1200 may include at least one processor and may control the overall operation of the test apparatus 1000A. The controller 1200 may include the temperature controller 1210.

The temperature controller 1210 may generate a pulse width modulation (PMW) signal based on the current temperature and the target set temperature, and may apply the generated PMW signal to the test socket 1100. The PMW signal generated by the temperature controller 1210 may be applied to the test socket 1100 as the control signal CTRL.

In some implementations, the temperature controller 1210 may perform inverse-compensation to control a duty ratio of the PWM signal when the current temperature is within a criteria temperature range. Accordingly, the temperature controller 1210 may precisely control a temperature inside the test socket 1100.

For example, the temperature controller 1210 according to some implementations may set the criteria temperature range such that the criteria temperature range includes the target set temperature. For example, the criteria temperature range may be set to be either lower than or equal to the target set temperature or higher than or equal to the target set temperature, depending on the target set temperature. For example, when the target set temperature is 70 degrees Celsius (° C.), the criteria temperature range may be either 69° C. to 70° C. or 70° C. to 71° C.

The duty ratio may refer to a ratio of time to an ON operation of the heater in a predetermined period. An example is provided in which the predetermined period is 30 milliseconds (msec). When the duty ratio is 100%, the heater may continue to perform an ON operation for 30 msec. When the duty ratio is 50%, the heater may perform an ON operation for 15 msec, half of the predetermined period.

A time point, at which a signal controlling the duty ratio is input to the test socket 1100, may not match a time point at which the temperature inside the test socket 1100 or the temperature of the image sensor module 1400 actually increases or decreases depending on the input signal. For example, even when a signal reducing the duty ratio is applied to the test socket 1100 while the current temperature is increasing, the temperature inside the test socket 1100 may continue to increase rather than decreasing immediately, which prevents the temperature inside the test socket 1100 from being precisely controlled.

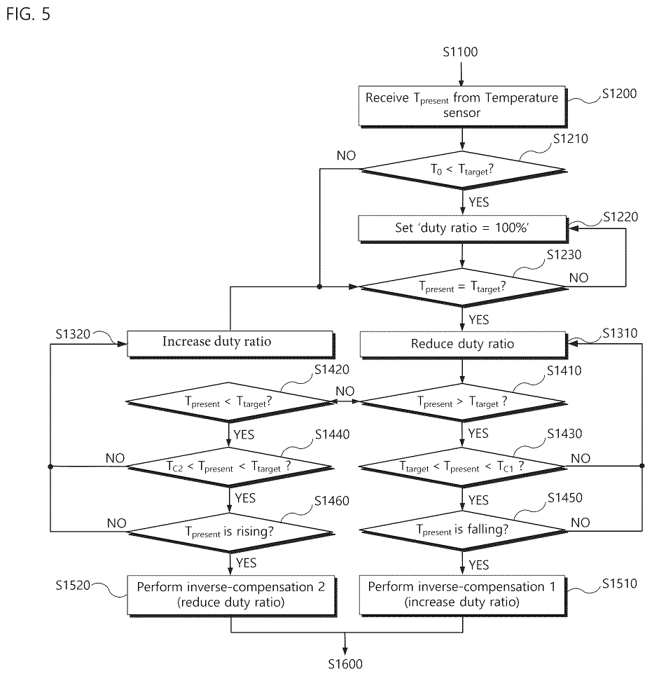

To precisely control the temperature inside the test socket 1100, the temperature controller 1210 according to some implementations may perform inverse-compensation to control a duty ratio of a pulse width modulation signal when the current temperature is within the criteria temperature range. A temperature control method of the temperature controller 1210 will be described in detail later with reference to FIG. 5.

The input/output unit 1300 may receive the target set temperature from an external entity. The input/output unit 1300 may transmit the received target set temperature to the temperature controller 1210.

The input/output unit 1300 may receive and output an image captured by the image sensor module 1400. In some implementations, a determination may be made as to whether the image sensor module 1400 operates normally at the target set temperature, a high temperature, based on the image output by the input/output unit 1300. However, this is only an example and, according to some implementations, the input/output unit 1300 may receive an image captured by the image sensor module 1400, generate a temperature evaluation result of the image sensor module 1400 based on the received image, and output the generated temperature evaluation result.

According to some implementations, the input/output unit 1300 may receive and output the current temperature TMC_{HS} from the controller 1200. According to some implementations, the input/output unit 1300 may receive and output the current temperature TMC_{IS} from the image sensor module 1400. For example, the input/output unit 1300 may visualize the current temperature as a temperature-time graph and output the visualized current temperature.

The input/output unit 1300 may include an input device such as a keyboard, a keypad, a touchpad, a touchscreen, a mouse, a remote controller, or the like, and an output device such as a display, a speaker, a printer, or the like.

The image sensor module 1400 may include an image sensor. The image sensor may include a charge-coupled device (CCD) sensor and/or a complementary metal oxide semiconductor (CMOS) sensor. However, implementations are not limited thereto, and the image sensor module 1400 may include a component, requiring a high-temperature test, other than the image sensor. The image sensor module 1400 may transmit the temperature TMC_{IS} measured by the module temperature sensor and the captured image to the input/output unit 1300.

As described above, the test socket 1100 of the test apparatus 1000A according to some implementations may have a socket structure optimized for the image sensor module 1400. Due to such a structure, components other than the image sensor module 1400 may not be exposed to high temperature. Accordingly, test errors caused by the components other than the image sensor module 1400 may be prevented, and temperature evaluation of the image sensor module 1400 may be efficiently performed at high temperature.

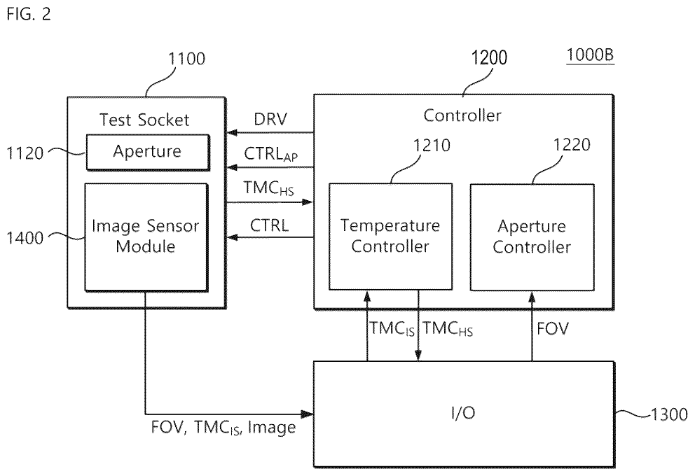

FIG. 2 is a block diagram illustrating an example of a test apparatus according to some implementations. A test apparatus 1000B of FIG. 2 is similar to the test apparatus 1000A of FIG.

1. Therefore, the same or similar components are denoted by the same or similar reference numerals, and redundant descriptions will be omitted below.

As compared to the test apparatus 1000A of FIG. 1, the test socket 1100 of the test apparatus 1000B may further include an aperture 1120, and the controller 1200 may further include an aperture controller 1220.

The aperture 1120 may adjust the amount of light provided to the image sensor module 1400. For example, the aperture 1120 may be opened or closed based on field of view (FOV) information to adjust the amount of light provided to the image sensor module 1400. According to some implementations, the aperture 1120 may be disposed above the image sensor module 1400.

The aperture controller 1220 may control the amount of light provided to the image sensor module 1400 by opening and closing the aperture 1120. For example, when the current temperature has been maintained at the target set temperature for a predetermined period of time, the aperture controller 1220 may transmit an aperture control signal CTRL_{AP} to the test socket 1100. The test socket 1100 may open and close the aperture in response to the aperture control signal CTRL_{AP}, and thus the amount of light provided to the image sensor module 1400 may be controlled.

According to some implementations, the aperture controller 1220 may control the degree to which an aperture is opened and closed, based on the FOV information. The FOV information, as a predetermined FOV range, may be a value stored in the image sensor module 1400. In some implementations, the FOV information may be an FOV range input by a user through the input/output unit 1300.

For example, when FOV information is a value stored in the image sensor module 1400, the image sensor module 1400 may transmit the FOV information to the input/output unit 1300, and the input/output unit 1300 may provide the received FOV information to the aperture controller 1220. For example, when the FOV information is an FOV range input by a user, the user may input the FOV range through the input/output unit 1300, and the input/output unit 1300 may transmit the input FOV information to the aperture controller 1220.

In some implementations, the image sensor module 1400 may be driven during a test operation to capture an image. For example, the aperture controller 1220 may transmit the aperture control signal CTRL_{AP} to the test socket 1100, and thus the aperture 1120 may be opened and closed depending on a set FOV range. The controller 1200 may transmit a driving signal DRV to the test socket 1100, and the image sensor module 1400 may capture an image based on the driving signal DRV. The image captured by the image sensor module 1400 may be provided to the input/output unit 1300 and may be used to determine whether the image sensor module 1400 operates normally at the target set temperature, a high temperature. Relative timings of the driving signals DRV and the aperture control signal CTRL_{AP} can vary in different implementations and in different conditions and target conditions.

For example, when high-temperature operation characteristics of the image sensor module 1400 are to be tested in a bright environment, the aperture control signal CTRL_{AP} and the driving signal DRV may be transmitted to the test socket 1100 substantially simultaneously. Accordingly, temperature evaluation of the image sensor module 1400 may be performed in the bright environment while significantly reducing heat loss of the test socket 1100.

For example, when high-temperature operation characteristics of the image sensor module 1400 are to be tested in a dark environment, the image sensor module 1400 may be driven based on the driving signal DRV while the aperture is closed or almost closed based on the aperture control signal CTRL_{AP}. Accordingly, temperature evaluation of the image sensor module 1400 may be performed in the dark environment.

As described above, the test socket 1100 of the test apparatus 1000B according to some implementations not only may efficiently perform temperature evaluation of the image sensor module 1400 at high temperature, but also may perform an image capturing test simultaneously or in a same testing operation with the high-temperature test. Accordingly, the test apparatus 1000B according to some implementations may save space and time for performing both the high-temperature test and the image capturing test.

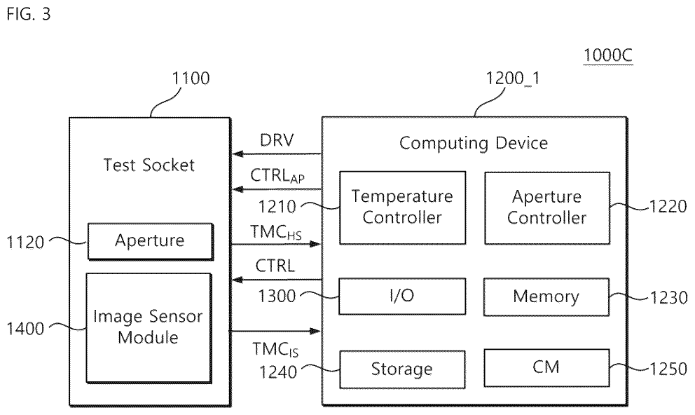

FIG. 3 is a block diagram illustrating a more detailed example in which a test apparatus 1000C is implemented in hardware. The test apparatus 1000C of FIG. 3 is similar to the test apparatuses 1000A and 1000B of FIGS. 1 and 2. Therefore, the same or similar components are denoted by the same or similar reference numerals, and redundant descriptions will be omitted below.

Referring to FIG. 3, the test apparatus 1000C may include a test socket 1100 and a computing device 1200_1.

The test apparatus 1000C according to some implementations may fix a removable test socket 1100 to a test module substrate including an image sensor module 1400. Thus, the image sensor module 1400 may be disposed inside the test socket 1100. In addition, various characteristics of the image sensor module may be tested at high temperatures using a controller 1200 and an input/output unit 1300. The test socket 1100 may emit heat such that a current temperature of the image sensor module 1400 reaches a target set temperature.

The computing device 1200_1 may include a temperature controller 1210, an aperture controller 1220, an input/output unit (I/O) 1300, a memory 1230, a storage device 1240, and a communication module (CM) 1250.

The computing device 1200_1 may include a central processing unit (CPU), a graphics processing unit (GPU), a programmable logic device, a specific-purpose processor electronic device, a microcontroller, and/or a microprocessor. The computing device 1200_1 may be implemented as a stationary computing device such as a desktop computer, a workstation, or a server, or may be implemented as a portable computing device such as a laptop computer. The computing device 1200_1 may be implemented as a mobile device such as a mobile phone, a smartphone, or a tablet personal computer (PC).

The temperature controller 1210 may transmit a control signal CTRL based on a pulse width modulation (PMW) signal to the test socket 1100. Thus, the test socket 1100 may precisely control a temperature based on the control signal CTRL of the temperature controller 1210.

The aperture controller 1220 may open and close an aperture 1120 based on field of view (FOV) information. The aperture controller 1220 may transmit a control signal CTRL_{AP} for opening and closing the aperture 1120 to the test socket 1100.

The memory 1230 may be implemented as a volatile memory such as a DRAM. The memory 1230 may temporarily store data received from the test socket 1100 or data to be transmitted to the test socket 1100. For example, the memory 1230 may temporarily store current temperature data based on time received from the test socket 1100, a temperature evaluation result, FOV information, and/or the like.

The storage device 1240, as a non-transitory storage medium, is capable of retaining stored data even when power supplied to the computing device 1200_1 is cut off. The storage device 1240 may be implemented as a nonvolatile memory such as an EEPROM, a flash memory, a phase-change random access memory (PRAM), a resistance random access memory (RRAM), a nano floating gate memory (NFGM), a polymer random access memory (PoRAM), a magnetic random access memory (MRAM), a ferroelectric random access memory (FRAM), or the like. In some implementations, the storage device 1240 may be implemented to be removable from the computing device 1200_1, such as an external USB hard disk. The storage device 1240 may store a temperature evaluation result for the image sensor module 1400, FOV information for the image sensor module 1400, and/or the like.

The communication module (CM) 1250 may provide access to a communication network outside the computing device 1200_1. For example, a network may include a plurality of computing systems and a plurality of communication links, and the communication links may include wired links, optical links, wireless links, or any other type of links.

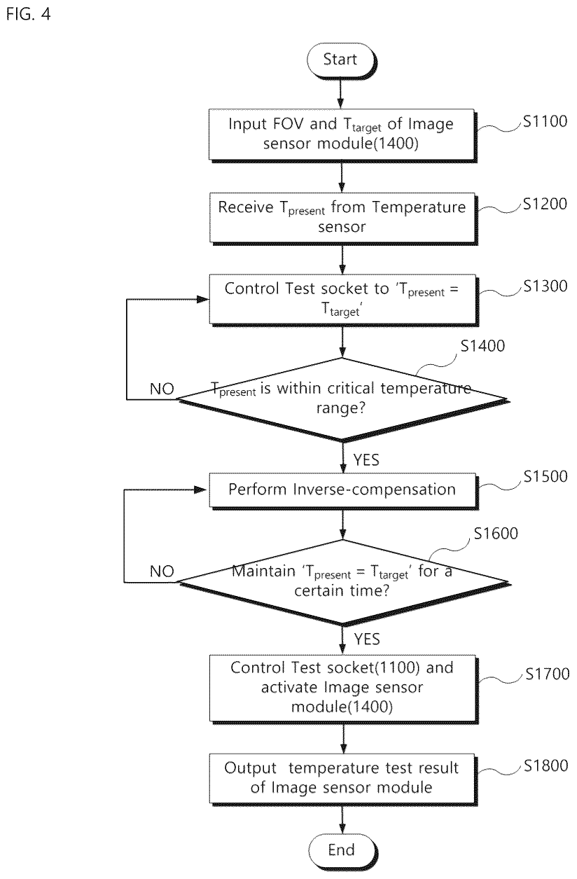

FIG. 4 is a flowchart illustrating an example of operation of a temperature controller of any of the test apparatuses of FIGS. 1-3. For ease of description, an example will be provided in which the test apparatus of FIG. 4 is the test apparatus 1000B of FIG. 2.

Referring to FIG. 4, in operation S1100, a predetermined field of view (FOV) information for the image sensor module 1400 and target set temperature T_{target} for temperature evaluation may be received. For example, the temperature controller 1210 may receive the FOV information and the target set temperature T_{target} of the image sensor module 1400 through the input/output unit 1300.

In operation S1200, a current temperature Tₚᵣₑₛₑₙₜ inside the test socket 1100 may be received. For example, a socket temperature sensor disposed inside the test socket 1100 may measure the current temperature Tₚᵣₑₛₑₙₜ, and the temperature controller 1210 may receive the measured current temperature Tₚᵣₑₛₑₙₜ. In some implementations, for example, a module temperature sensor disposed inside the image sensor module 1400 may measure the current temperature Tₚᵣₑₛₑₙₜ and transmit the measured current temperature Tₚᵣₑₛₑₙₜ to the input/output unit 1300. The temperature controller 1210 may receive the measured current temperature Tₚᵣₑₛₑₙₜ through the input/output unit 1300.

In operation S1300, the test socket 1100 may be controlled such that the current temperature Tₚᵣₑₛₑₙₜ reaches the target set temperature T_{target} based on a pulse width modulation (PWM) signal. For example, the temperature controller 1210 may transmit a control signal CTRL to the test socket 1100 such that the current temperature Tₚᵣₑₛₑₙₜ reaches the target set temperature T_{target}. The test socket 1100 may emit heat such that the current temperature Tₚᵣₑₛₑₙₜ reaches the target set temperature T_{target}, in response to the control signal CTRL

In operation S1400, a determination may be made as to whether the current temperature Tₚᵣₑₛₑₙₜ is within a criteria temperature range. For example, the criteria temperature range may include a first criteria temperature range and a second criteria temperature range. The first criteria temperature range may be temperature range between the target set temperature T_{target} and the first criteria temperature. The first criteria temperature may be an upper bounding temperature of the criteria temperature range. The second criteria temperature range may be temperature range between the target set temperature T_{target} and the second criteria temperature. The second criteria temperature is a lower bounding temperature of the criteria temperature range.

The temperature controller 1210 may determine whether the current temperature Tₚᵣₑₛₑₙₜ is within either the first criteria temperature range or the second criteria temperature range.

When the current temperature Tₚᵣₑₛₑₙₜ is within the criteria temperature range, the flow proceeds to operation S1500 in which inverse-compensation may be performed based on a duty ratio of the PWM signal. For example, the temperature controller 1210 may vary the duty ratio of the PWM signal to perform the inverse-compensation, and may transmit the varied PWM signal to the test socket 1100 as a control signal (CTRL). When the current temperature Tₚᵣₑₛₑₙₜ is not within the criteria temperature range, the process returns to operation S1300.

In operation S1600, a determination may be made as to whether the current temperature Tₚᵣₑₛₑₙₜ is maintained at the target set temperature T_{target} for a predetermined time. For example, the temperature controller 1210 may determine whether the current temperature Tₚᵣₑₛₑₙₜ is maintained at the target set temperature T_{target} for a predetermined time.

When the current temperature Tₚᵣₑₛₑₙₜ is maintained at the target set temperature T_{target} for a predetermined time, the flow proceeds to operation S1700 in which the test socket 1100 and the image sensor module 1400 may be driven for a test operation at high temperature. For example, the aperture controller 1220 may open and close the aperture of the test socket 1100 based on the FOV information. The controller 1200 may drive the image sensor module 1400 to capture an image. When the current temperature Tₚᵣₑₛₑₙₜ is not maintained at the target set temperature T_{target} for the predetermined time, the process returns to operation S1500.

In operation S1800, a temperature evaluation result of the image sensor module may be output. For example, the input/output unit 1300 may receive an image captured by the image sensor module 1400. The temperature evaluation result of the image sensor module 1400 may be output based on the received image.

As described above, the test apparatus according to some implementations may efficiently perform temperature evaluation on the image sensor module at high temperatures using a test socket optimized for the image sensor module.

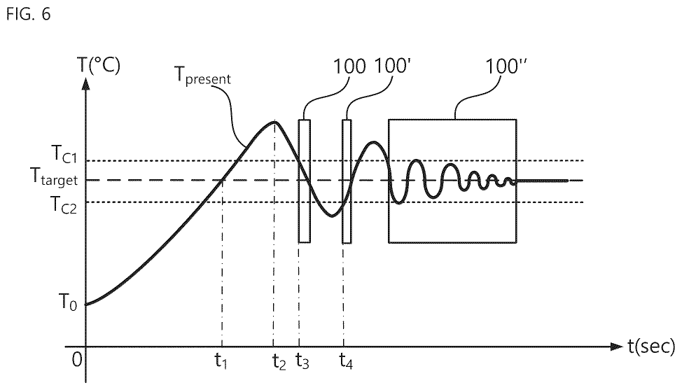

FIG. 5 is a flowchart illustrating a detailed example of the temperature control of FIG. 4. FIG. 6 is a graph illustrating an example of the current temperature Tₚᵣₑₛₑₙₜ over time. The operation of the test apparatus of FIG. 5 is similar to the operation of the test operation of FIG. 4. Accordingly, the same or similar operations are denoted by the same or similar reference numerals, and redundant descriptions will be omitted below.

Referring to FIG. 5, in operation S1200, current temperature Tₚᵣₑₛₑₙₜ inside the test socket 1100 may be received.

In operation S1210, a determination may be made as to whether an initial current temperature T₀ is lower than a target set temperature T_{target}. For example, the temperature controller 1210 may determine whether the initial current temperature T₀ is lower than the target set temperature T_{target}. In general, before starting temperature evaluation, the initial current temperature T₀ of the image sensor module 1400 may be lower than the target set temperature T_{target}.

When the initial current temperature T₀ is lower than the target set temperature T_{target}, for example, when Tₒ<T_{target}, the flow proceeds to operation S1220 in which a duty ratio of a pulse width modulation (PWM) signal may be controlled to have a large value. For example, the temperature controller 1210 may control the duty ratio of the PWM signal to 100% (though implementations are not limited thereto). Thus, a heater of the test socket 1100 may continuously operate in a turned-on state, and the temperature inside the test socket 1100 may rapidly increase.

For example, referring to FIG. 6, an initial current temperature of the image sensor module 1400 may be T₀, and T₀ may be lower than the target temperature T_{target}. Accordingly, the temperature controller 1210 may generate the control signal CTRL such that a duty ratio of the PWM signal is 100%, and the heater may emit heat based on the control signal CTRL. As a result, the current temperature Tₚᵣₑₛₑₙₜ may relatively rapidly increase to the target set temperature T_{target}.

Returning to FIG. 5, when T₀ is not lower than T_{target}, the flow proceeds to operation S1230.

In operation S1230, a determination may be made as to whether the current temperature Tₚᵣₑₛₑₙₜ has reached the target set temperature T_{target}. For example, the temperature controller 1210 may determine whether the current temperature Tₚᵣₑₛₑₙₜ has reached the target set temperature T_{target}, for example, Tₚᵣₑₛₑₙₜ=T_{target}.

When the current temperature Tₚᵣₑₛₑₙₜ reaches the target set temperature T_{target}, the flow proceeds to operation S1310 in which the duty ratio of the PWM signal may be reduced. For example, the temperature controller 1210 may reduce the duty ratio of the PWM signal to less than 100% or less than its prior value in operation S1220.

For example, referring to FIG. 6, at a first time point t1, the current temperature Tₚᵣₑₛₑₙₜ reaches the target set temperature T_{target}. In this case, at the first time point t1, the temperature controller 1210 may reduce the duty ratio of the PWM signal. Accordingly, the heat emitted by the heater may be reduced, and the temperature inside the test socket 1100 in a high-temperature state may decrease.

However, there is a time lag between a time point, at which the temperature controller 1210 reduces the duty ratio of the PWM signal, and a time point at which the temperature inside the test socket 1100 is actually changed, so that the temperature inside the test socket 1100 continues to increase for a predetermined time even when the duty ratio of the PWM signal is reduced. For example, as illustrated in FIG. 6, the temperature inside the test socket 1100 may continue to increase until a second time point t2, and may then decrease.

When the current temperature Tₚᵣₑₛₑₙₜ has not reached the target set temperature T_{target}, the duty ratio of the pulse puck modulation signal may be continuously maintained at a large value.

In operation S1410, a determination may be made as to whether the current temperature Tₚᵣₑₛₑₙₜ is higher than the target set temperature T_{target}. For example, a determination may be made to whether Tₚᵣₑₛₑₙₜ>T_{target}. For example, the temperature controller 1210 may determine whether the current temperature Tₚᵣₑₛₑₙₜ is higher than the target set temperature T_{target}.

When Tₚᵣₑₛₑₙₜ>T_{target}, the flow proceeds to operation S1430 in which a determination may be made as to whether the current temperature Tₚᵣₑₛₑₙₜ is within the first criteria temperature range. For example, a determination may be made as to whether T_{target}<Tₚᵣₑₛₑₙₜ<T_{C1}. For example, the temperature controller 1210 may determine whether the current temperature Tₚᵣₑₛₑₙₜ is within a range between the target set temperature T_{target} and the first criteria temperature T_{C1}.

When the current temperature Tₚᵣₑₛₑₙₜ is not within the first criteria temperature range, the flow returns to operation S1310.

When the current temperature Tₚᵣₑₛₑₙₜ is within the first criteria temperature range, for example, when T_{target}<Tₚᵣₑₛₑₙₜ<T_{C1}, the flow proceeds to S1450 in which a determination may be made as to whether the current temperature Tₚᵣₑₛₑₙₜ is decreasing. For example, the temperature controller 1210 may determine whether the current temperature Tₚᵣₑₛₑₙₜ is decreasing based on s temperature deviation at a past time point.

When it is determined that the current temperature Tₚᵣₑₛₑₙₜ is decreasing, the flow proceeds to operation S1510 in which first inverse-compensation may be performed. The first inverse-compensation may refer to an operation of increasing the duty ratio of the PWM signal even when the current temperature Tₚᵣₑₛₑₙₜ is higher than the target set temperature T_{target}. For example, even when the current temperature Tₚᵣₑₛₑₙₜ is within the first criteria temperature range and is higher than the target set temperature T_{target}, the temperature controller 1210 may increase the duty ratio of the PWM signal.

For example, referring to FIG. 6, at third time point t3, the current temperature T present is within the first criteria temperature range 100 and is decreasing. For example, the current temperature Tₚᵣₑₛₑₙₜ is within a range between the first criteria temperature T_{C1} and the target set temperature T_{target} and is decreasing. In this case, the temperature controller 1210 may perform first inverse-compensation to increase the duty ratio of the PWM signal. Accordingly, a rate at which the current temperature Tₚᵣₑₛₑₙₜ decreases may be reduced, and a deviation between the current temperature Tₚᵣₑₛₑₙₜ and the target set temperature T_{target} may be reduced. Then, the flow proceeds to operation S1600.

When it is determined that the current temperature Tₚᵣₑₛₑₙₜ is not decreasing, the flow returns to operation S1310. For example, when it is determined that the current temperature Tₚᵣₑₛₑₙₜ is increasing, the temperature controller 1210 may decrease the duty ratio because the current temperature Tₚᵣₑₛₑₙₜ is higher than the target set temperature T_{target}.

In operation S1410, when Tₚᵣₑₛₑₙₜ>T_{target}, the flow proceeds to S1420. In operation S1420, a determination may be made as to whether the current temperature Tₚᵣₑₛₑₙₜ is lower than the target set temperature T_{target}. For example, a determination may be made as to whether Tₚᵣₑₛₑₙₜ<T_{target}. For example, the temperature controller 1210 may determine whether the current temperature Tₚᵣₑₛₑₙₜ is lower than the target set temperature T_{target}.

When Tₚᵣₑₛₑₙₜ<T_{target}, the flow proceeds to operation S1440 in which a determination may be made as to whether the current temperature Tₚᵣₑₛₑₙₜ is within the second criteria temperature range. For example, a determination may be made as to whether T_{C2}<Tₚᵣₑₛₑₙₜ<T_{target}. For example, the temperature controller 1210 may determine whether the current temperature Tₚᵣₑₛₑₙₜ is within the second criteria temperature T_{C2} or the target set temperature T_{target}.

When the current temperature Tₚᵣₑₛₑₙₜ is not within the second criteria temperature range, the flow proceeds to operation S1320. In operation S1320, the duty ratio may increase. For example, the current temperature Tₚᵣₑₛₑₙₜ is lower than the target set temperature T_{target}, so that the temperature controller 1210 may increase the duty ratio of the PWM signal.

When the current temperature Tₚᵣₑₛₑₙₜ is within the second criteria temperature range, for example, when T_{C2}<Tₚᵣₑₛₑₙₜ<T_{target}, the flow proceeds to operation S1460 in which a determination may be made as to whether the current temperature Tₚᵣₑₛₑₙₜ is increasing. For example, the temperature controller 1210 may determine whether the current temperature Tₚᵣₑₛₑₙₜ is increasing, based on the temperature deviation at a past time point.

When the current temperature Tₚᵣₑₛₑₙₜ is increasing, the flow proceeds to operation S1520 in which the second inverse-compensation may be performed. The second inverse-compensation may refer to an operation of reducing the duty ratio of the PWM signal even when the current temperature Tₚᵣₑₛₑₙₜ is lower than the target set temperature T_{target}. For example, the temperature controller 1210 may reduce the duty ratio of the PWM signal even when the current temperature Tₚᵣₑₛₑₙₜ is lower than the target set temperature T_{target}. Then, the flow proceeds to operation S1600.

For example, referring to FIG. 6, at fourth time point t4, the current temperature Tₚᵣₑₛₑₙₜ may be within a second criteria temperature range 100′ and may be increasing. For example, the current temperature Tₚᵣₑₛₑₙₜ may be within a range between the target set temperature T_{target} and the second criteria temperature T_{C2} and may be increasing. In this case, the temperature controller 1210 may perform second inverse-compensation to reduce the duty ratio of the PWM signal. Accordingly, a rate at which the current temperature Tₚᵣₑₛₑₙₜ increases may be reduced, and a deviation between the current temperature Tₚᵣₑₛₑₙₜ and the target set temperature T_{target} may be reduced. Then, the flow proceeds to operation S1600.

When it is determined that the current temperature Tₚᵣₑₛₑₙₜ is not increasing, the flow returns to operation S1320. For example, when it is determined that the current temperature Tₚᵣₑₛₑₙₜ is decreasing, the temperature controller 1210 may increase the duty ratio because the current temperature Tₚᵣₑₛₑₙₜ is lower than the target set temperature T_{target}.

As described above, the test apparatus according to some implementations may perform inverse-compensation based on whether the current temperature is within a criteria temperature range and whether the current temperature is increasing or decreasing. Accordingly, as illustrated in FIG. 6, the current temperature Tₚᵣₑₛₑₙₜ may repeatedly increase and decrease within a criteria temperature range 100″, and a deviation from the target set temperature T_{target} may be gradually reduced. Through such a process, the test apparatus according to some implementations may determine an optimal duty ratio, and the current temperature Tₚᵣₑₛₑₙₜ may be maintained at the target set temperature T_{target} for a predetermined time.

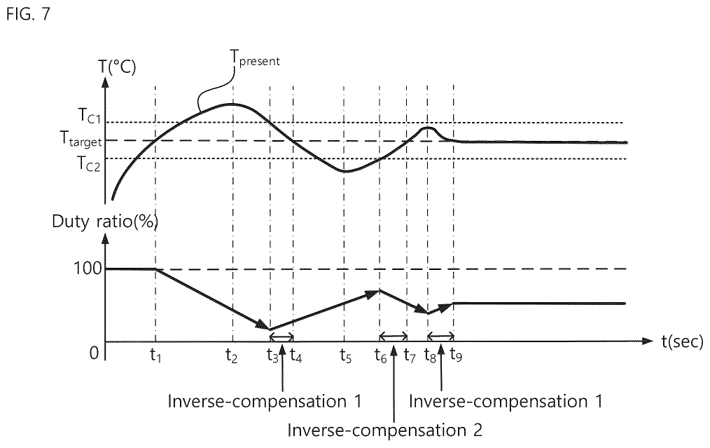

FIG. 7 is a diagram illustrating an example of a process in which an optimal duty ratio is determined, according to some implementations. For example, FIG. 7 illustrates a graph of current temperature over time and a graph of duty ratio of a pulse width modulation (PWM) signal over time.

Referring to FIG. 7, at first time point t1, the current temperature Tₚᵣₑₛₑₙₜ and the target set temperature T_{target} may be the same. For example, Tₚᵣₑₛₑₙₜ=T_{target}. In this case, the PWM signal may be controlled to have as large a duty ratio as possible. For example, the duty ratio of the PWM signal may be 100%.

Between first time point t1 and second time point t2, the current temperature Tₚᵣₑₛₑₙₜ may be greater than the target set temperature T_{target} (for example, Tₚᵣₑₛₑₙₜ>T_{target}), and the current temperature Tₚᵣₑₛₑₙₜ may be increasing. In this case, the temperature controller 1210 may reduce the duty ratio of the PWM signal to decrease the current temperature Tₚᵣₑₛₑₙₜ.

Between second time point t2 and third time point t3, the current temperature Tₚᵣₑₛₑₙₜ may be greater than the first criteria temperature T_{C1} (for example, Tₚᵣₑₛₑₙₜ>T_{C1}), and the current temperature Tₚᵣₑₛₑₙₜ may be decreasing. In this case, the temperature controller 1210 may continue to reduce the duty ratio to decrease the current temperature Tₚᵣₑₛₑₙₜ.

Between third time point t3 and fourth time point t4, the current temperature Tₚᵣₑₛₑₙₜ may be within a first criteria temperature range 100 (for example, T_{target}<Tₚᵣₑₛₑₙₜ<T_{C1}), and the current temperature Tₚᵣₑₛₑₙₜ may be decreasing. In this case, the temperature controller 1210 may increase the duty ratio of the PWM signal to reduce the deviation between the current temperature Tₚᵣₑₛₑₙₜand the target set temperature T_{target}. For example, first inverse-compensation may be performed to reduce the degree to which the current temperature Tₚᵣₑₛₑₙₜ decreases.

Between fourth time point t4 and fifth time point t5, the current temperature Tₚᵣₑₛₑₙₜ may be smaller than the target set temperature T_{target} (for example, Tₚᵣₑₛₑₙₜ<T_{target}), and the current temperature Tₚᵣₑₛₑₙₜ may be decreasing. In this case, the temperature controller 1210 may increase the duty ratio of the PWM signal to increase the current temperature Tₚᵣₑₛₑₙₜ.

Between fifth time point t5 and sixth time point t6, the current temperature T ₚᵣₑₛₑₙₜ may be smaller than the second criteria temperature T_{C2} (for example, Tₚᵣₑₛₑₙₜ<T_{C2}), and the current temperature Tₚᵣₑₛₑₙₜ is increasing. In this case, the temperature controller 1210 may continue to increase the duty ratio of the PWM signal to increase the current temperature Tₚᵣₑₛₑₙₜ.

Between sixth time point t6 and seventh time point t7, the current temperature Tₚᵣₑₛₑₙₜ may be within a second criteria temperature range 100′ (for example, T_{C2} <Tₚᵣₑₛₑₙₜ<T_{target}), and the current temperature Tₚᵣₑₛₑₙₜ may be increasing. In this case, the temperature controller 1210 may reduce the duty ratio of the PWM signal to reduce the deviation between the current temperature Tₚᵣₑₛₑₙₜ and the target set temperature T_{target}. For example, second inverse-compensation may be performed to reduce the degree to which the current temperature Tₚᵣₑₛₑₙₜ increases.

Between seventh time point t7 to eighth time point t8, the current temperature T present may be greater than the target set temperature T_{target} (for example, Tₚᵣₑₛₑₙₜ>T_{target}), and the current temperature Tₚᵣₑₛₑₙₜ may be increasing. In this case, the temperature controller 1210 may reduce the duty ratio of the PWM signal to reduce the current temperature Tₚᵣₑₛₑₙₜ.

Between eighth time point t8 and ninth time point t9, the current temperature Tₚᵣₑₛₑₙₜ may be within the first criteria temperature range 100 (for example, T_{target}<Tₚᵣₑₛₑₙₜ<T_{C1}), and the current temperature Tₚᵣₑₛₑₙₜ may be decreasing. In this case, the temperature controller 1210 may increase the duty ratio of the PWM signal to reduce the deviation between the current temperature Tₚᵣₑₛₑₙₜ and the target set temperature T_{target}. For example, the first inverse-compensation may be re-performed to reduce the degree to which the current temperature Tₚᵣₑₛₑₙₜ decreases.

After ninth time point t9, the current temperature Tₚᵣₑₛₑₙₜ may be maintained at the target set temperature T_{target} for a certain time. In this case, the duty ratio of the PWM signal may also be maintained at a constant value. Thus, a high temperature test of the image sensor module 1400 may be performed at the target set temperature T_{target}.

As described above, small-sized test sockets are often susceptible to external impact (e.g., are significantly influenced by external temperatures), and thus have difficulty in maintaining a desired target temperature during a high-temperature test. However, the temperature controller 1210 according to some implementations may maintain the target temperature of the small-sized test socket 1100 at a constant temperature by performing precise temperature control through inverse-compensation. Accordingly, test errors may be significantly reduced. For example, the test apparatuses 1000A, 1000B, 1000C according to some implementations may perform efficient and reliable temperature evaluation while using the small-sized test socket 1100.

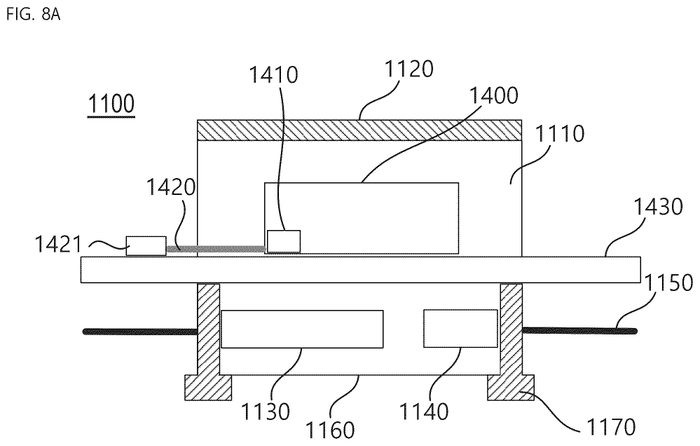

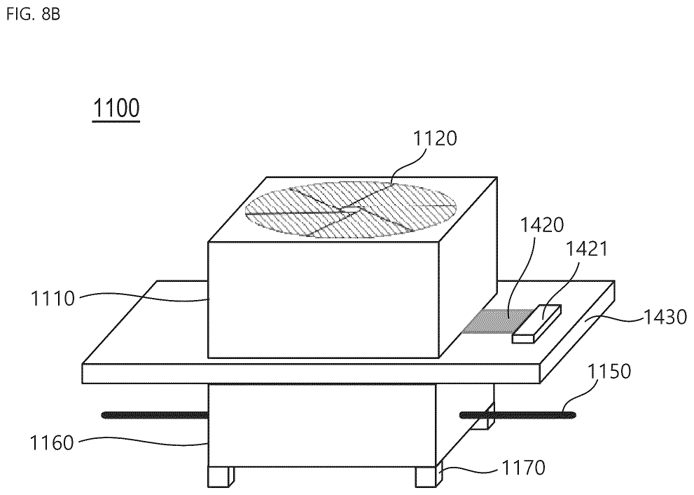

FIG. 8A is a diagram illustrating an example of a cross-sectional view of a test socket 1100, and FIG. 8B is a diagram illustrating the test socket 1100 of FIG. 8A. The test socket 1100 of FIGS. 8A and 8B can be used as the test socket 1100 of FIGS. 1 to 3. Accordingly, the same or similar components are denoted by the same or similar reference numerals, and redundant descriptions will be omitted below.

Referring to FIGS. 8A and 8B, the test socket 1100 may include a cover 1110, an aperture 1120, a heater 1130, a socket temperature sensor 1140, a wire 1150, a bottom plate 1160, and a support 1170.

The test socket 1100 may have a structure surrounding the image sensor module 1400. The test socket 1100 may emit heat to the image sensor module 1400 such that the current temperature reaches the target set temperature.

The image sensor module 1400 may be provided in various forms, and the test socket 1100 may have various forms corresponding thereto. FIGS. 8A and 8B illustrate only an example of the test socket 1100, an implementations are not limited thereto.

The cover 1110 may cover an upper portion of the image sensor module 1400. Accordingly, during temperature evaluation, a high target temperature may be stably maintained and heat loss may be prevented.

The aperture 1120 may be disposed above the image sensor module 1400 and may be opened and closed based on field of view (FOV) information. The aperture 1120 may be disposed above the cover 1110, and may control the amount of light provided to the image sensor module 1400.

The heater 1130 may be turned on and turned off based on a duty ratio of a pulse width modulation (PWM) signal. The heater 1130 may emit heat into the test socket 1100 such that current temperature reaches target set temperature. The heater 1130 may be turned on and turned off based on the PWM signal, and the duty ratio of the PWM signal may be precisely controlled by the temperature controller 1200. Accordingly, the temperature inside the test socket 1100 may rapidly reach the high target set temperature, and the high target set temperature may be stably maintained.

The socket temperature sensor 1140 may measure the current temperature inside the test socket 1100. The socket temperature sensor 1140 may be disposed below the image sensor module 1400 together with the heater 1130.

The bottom plate 1160 may be disposed below the image sensor module 1400. For example, the bottom plate 1160 may have a shape surrounding a lower portion of the image sensor module 1400. The bottom plate 1160 may define an empty space, and the heater 1130 and the socket temperature sensor 1140 may be disposed in the empty space.

The heater 1130 and the socket temperature sensor 1140 may be connected to the controller 1200 through the bottom plate 1160 by the wire 1150. The wire 1150 may connect the aperture 1120 and the controller 1200. The wire 1150 may provide a path along which data of the aperture 1120, heater 1130, and socket temperature sensor 1140 is transmitted to the controller 1200. Also, the wire 1150 may provide a path along which a control signal of the controller 1200 is transmitted to the aperture 1120, the heater 1130, and the socket temperature sensor 1140.

The support 1170 may stably support the bottom plate 1160. The support 1170 may be provided in singular or plural and may have a shape varying depending on the image sensor module 1400.

The cover 1110 may be coupled to and separated from the bottom plate 1160. For example, the cover 1110 and the bottom plate 1160 may be completely separated, e.g., spaced apart from one another. Alternatively, one surface of the cover 1110 and one surface of the bottom plate 1160 may be hingedly connected to each other. Accordingly, the cover 1110 and the bottom plate 1160 may be coupled to and controllably separated from each other in such a manner that the cover 1110 and one side/surface of the bottom plate 1160 are opened and closed.

The image sensor module 1400 may include a module temperature sensor 1410, a flexible printed circuit board (FPCB) 1420 for testing, an FPCB connector 1421, and a substrate 1430.

The module temperature sensor 1410 may be disposed inside the image sensor module 1400, and may measure the current temperature.

The FPCB 1420 may be a flexible circuit board for controlling temperature evaluation. The FPCB 1420 may be a circuit board, removable from the image sensor module 1400 undergoing temperature evaluation. The FPCB 1420, as a small-sized board, may be efficient when there is a spatial limitation. For example, the FPCB 1420 may apply a voltage to the image sensor module 1400. The FPCB 1420 may transmit a control signal, and the image sensor module 1400 may be driven by the control signal. The FPCB 1420 may control not only the temperature evaluation of the image sensor module 1400, but also various evaluations.

The FPCB connector 1421 may be a connector for connecting an electronic device, such as an input/output unit 1300 and a computing device 1200, 1200_1, to the FPCB 1420. For example, the current temperature measured by the module temperature sensor 1410 may be transmitted to the input/output unit 1300 through the FPCB connector 1421.

The substrate 1430 may be a semiconductor substrate on which the image sensor module 1400 is manufactured and disposed.

The cover 1110 may have a shape surrounding an upper portion of the image sensor module 1400, centered on the substrate 1430 on which the image sensor module 1400 is disposed. The bottom plate 1160 may have a shape surrounding a lower portion of the image sensor module 1400, centered on the substrate 1430. However, this is only an example, and implementations are not limited thereto.

As described above, the test socket 1100 according to some implementations may have a small-sized socket structure optimized for an image sensor module. Due to such a structure, components other than the image sensor module may not be exposed to high temperatures, and test errors caused by components other than the image sensor module may be prevented. In addition, the test socket 1100 may perform an image capturing test simultaneously with a high-temperature test. As a result, the test apparatuses 1000A, 1000B, 1000C according to some implementations may perform efficient temperature evaluation at high temperature.

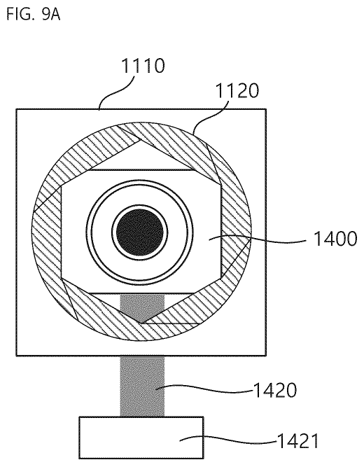

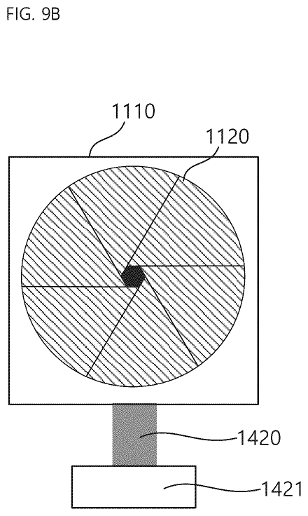

FIGS. 9A and 9B are diagrams illustrating an example of operation of the aperture 1120 of the test socket 1100 of FIGS. 8A and 8B. In detail, FIG. 9A is a schematic diagram illustrating a state in which the aperture 1120 disposed above the image sensor module 1400 is open, and FIG. 9B is a schematic diagram illustrating a state in which the aperture 1120 disposed above the image sensor module 1400 is closed.

The test socket 1100 of FIGS. 9A and 9B is similar to the test socket 1100 of FIGS. 1 to 3. Accordingly, the same or similar components are denoted by the same or similar reference numerals, and redundant descriptions will be omitted below.

Referring to FIG. 9A, when high-temperature operation characteristics of the image sensor module 1400 are tested in a bright environment, an aperture control signal CTRL_{AP} and a driving signal DRV can be transmitted to the test socket 1100 simultaneously or almost simultaneously. For example, when the current temperature is maintained at target set temperature for a predetermined time, the aperture controller 1220 may generate the aperture control signal CTRL_{AP} based on field of view (FOV) information. Then, the aperture controller 1220 may transmit the aperture control signal CTRL_{AP} to the aperture 1120, and the aperture 1120 may be opened in response to the aperture control signal CTRL_{AP}.

Thus, the FPCB 1420 may drive the image sensor module 1400 based on the driving signal DRV input through the FPCB connector 1421. For example, the image sensor module 1400 may capture an image of an upper portion at which the aperture 1120 is open. The aperture 1120 is opened based on an FOV of the image sensor module 1400, so that temperature evaluation of the image sensor module 1400 may be performed in a bright environment while significantly reducing heat loss.

Referring to FIG. 9B, when high-temperature operation characteristics of the image sensor module 1400 are tested in a dark environment, the image sensor module 1400 may be driven based on the driving signal DRV while the aperture control signal CTRL_{AP} is closed or almost closed. For example, when the current temperature is maintained at target set temperature for a predetermined time, the aperture controller 1220 may generate an aperture control signal CTRL_{AP} based on field of view (FOV) information and may transmit the aperture control signal CTRL_{AP} to the aperture 1120. Thus, the aperture 1120 may be closed in response to the aperture control signal CTRL_{AP}.

Then, the test FPCB 1420 may drive the image sensor module 1400 based on the driving signal DRV input through the FPCB connector 1421. For example, the image sensor module 1400 may capture an image of an upper portion at which the aperture 1120 is closed. Accordingly, temperature evaluation of the image sensor module 1400 may be performed in a dark environment. For example, the image sensor module 1400 captures an image in the dark environment in which the aperture 1120 is closed, so that dark characteristics of the image sensor module 1400 may be determined.

The image sensor module 1400 may transmit the captured image to the input/output unit 1300. Thus, the input/output unit 1300 may output a temperature evaluation result of the image sensor module 1400 based on the received image. A driving state of the image sensor module 1400 may be determined at a target set temperature, a high temperature, based on the image output by the input/output unit 1300.

As described above, the test socket 1100 according to some implementations may have a small-sized socket structure optimized for an image sensor module. Due to such a structure, components other than the image sensor module may not be exposed to high temperature. Accordingly, test errors caused by components other than the image sensor module may be prevented. In addition, the test socket 1100 may perform an image capturing test simultaneously with a high-temperature test. As a result, the test apparatuses 1000A, 1000B, 1000C according to some implementations may save space and time for a high-temperature test and an image capture test.

As set forth above, according to some implementations, a test socket optimized for an image sensor module, a test apparatus including the same, and a method of operating the same may be provided to stably perform temperature evaluation of the image sensor module.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While some examples have been shown and described above, it will be apparent to those skilled in the art that modifications and variations could be made without departing from the scope of this disclosure.

What is claimed is:

1. A test apparatus comprising:
a controller configured to generate a pulse width modulation signal to control a temperature of an image sensor module to be tested, and
a test socket configured to emit heat to the image sensor module based on the pulse width modulation signal,
wherein the controller is configured to control a duty ratio of the pulse width modulation signal based on a current temperature of the image sensor module, a target temperature and a criteria temperature range, and
the criteria temperature range is a temperature range within a preset range from the target temperature.

2. The test apparatus of claim 1, wherein the test socket comprises:
an aperture disposed above the image sensor module, the aperture configured to open and close;
a heater configured to turn on and off based on the pulse width modulation signal and configured to emit heat to control the current temperature; and
a socket temperature sensor configured to measure the current temperature.

3. The test apparatus of claim 2, further comprising:
an aperture controller configured to open or close the aperture using a field of view (FOV) signal based on the current temperature being maintained at the target temperature for a predetermined time.

4. The test apparatus of claim 3,
wherein the image sensor module is configured to capture an image while the aperture is open or closed based on the FOV signal, and
wherein the controller is further configured to determine a temperature evaluation result of the image sensor module based on the captured image.

5. The test apparatus of claim 2, wherein the controller is further configured to control times at which the heater is turned on or turned off by varying the duty ratio of the pulse width modulation signal.

6. The test apparatus of claim 1, wherein the controller is further configured to reduce the duty ratio of the pulse width modulation signal based on the current temperature being higher than the target temperature and based on the current temperature being outside the criteria temperature range.

7. The test apparatus of claim 1, wherein the controller is configured to increase the duty ratio of the pulse width modulation signal based on the current temperature decreasing while the current temperature is higher than the target temperature and lower than a first criteria temperature, and
the first criteria temperature is an upper bounding temperature of the criteria temperature range.

8. The test apparatus of claim 1, wherein the controller is configured to increase the duty ratio of the pulse width modulation signal based on the current temperature being lower than the target temperature and based on the current temperature being outside the criteria temperature range.

9. The test apparatus of claim 8, wherein the controller is configured to reduce the duty ratio of the pulse width modulation signal based on the current temperature increasing while the current temperature is higher than a second criteria temperature and lower than the target temperature, and
the second criteria temperature is a lower bounding temperature of the criteria temperature range.

10. The test apparatus of claim 1, wherein at least one of a module temperature sensor of the image sensor module and a socket temperature sensor of the test socket is configured to provide the current temperature.

11. A test socket comprising:
a cover covering an upper portion of an image sensor module to be tested;
an aperture configured to open and close based on an aperture control signal;
a heater configured to turn on and off based on a pulse width modulation signal and configured to emit heat to the image sensor module to cause a current temperature of the image sensor module to reach a target temperature;
a socket temperature sensor configured to measure the current temperature;
a bottom plate disposed below the image sensor module and accommodating the heater and the socket temperature sensor; and
a support supporting the bottom plate.

12. The test socket of claim 11, wherein
the aperture is disposed above the cover to control an amount of light received by the image sensor module.

13. The test socket of claim 11,
wherein the cover is coupled to and separated from the bottom plate, and
wherein the cover surrounds an upper portion of the image sensor module, and the bottom plate surrounds a lower portion of the image sensor module, the bottom plate centered on a substate on which the image sensor module is disposed.

14. The test socket of claim 11, wherein times at which the heater is turned on or off vary based on a duty ratio of the pulse width modulation signal.

15. A test method comprising:
receiving predetermined field of view (FOV) information and a target temperature for temperature evaluation of an image sensor module to be tested;
receiving a current temperature inside a test socket;
controlling the test socket, based on the current temperature being outside a criteria temperature range and based on the current temperature being lower than the target temperature, to cause the current temperature to increase using a pulse width modulation signal;
controlling the test socket, based on the current temperature being within the criteria temperature range and based on the current temperature being lower than the target temperature, to cause the current temperature to decrease using the pulse width modulation signal;
controlling the test socket based on the FOV information and driving the image sensor module to capture an image based on the current temperature being maintained at the target temperature for a predetermined time; and
outputting a result of the temperature evaluation of the image sensor module, the temperature evaluation based on the captured image.

16. The test method of claim 15, comprising
increasing the duty ratio of the pulse width modulation signal based on the current temperature decreasing while the current temperature is higher than the target temperature and lower than a first criteria temperature,
wherein the first criteria temperature is an upper bounding temperature of the criteria temperature range.

17. The test method of claim 16, comprising
reducing the duty ratio of the pulse width modulation signal based on the current temperature increasing while the current temperature is higher than a second criteria temperature and lower than the target temperature,
wherein the second criteria temperature is a lower bounding temperature of the criteria temperature range.

18. The test method of claim 15, comprising reducing the duty ratio of the pulse width modulation signal based on the current temperature being higher than the target temperature and based on the current temperature being outside the criteria temperature range.

19. The test method of claim 15, comprising increasing the duty ratio of the pulse width modulation signal based on the current temperature being lower than the target temperature and based on the current temperature being outside the criteria temperature range.

20. The test method of claim 15, wherein controlling the test socket based on the FOV information comprises opening or closing an aperture of the test socket.
